(19) United States
(12) Patent Application Publication
(10) Pub. No.: US 2009/0315096 A1
(43) Pub. Date: Dec. 24, 2009

(54) NON-VOLATILE MEMORY AND METHOD OF MANUFACTURING THE SAME

(75) Inventors: Houng-Chi Wei, Hsinchu City (TW); Chien-Lung Chu, Taipei County (TW); Saysamone Pittikoun, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: POWERCHIP SEMICONDUCTOR CORP., Hsinchu (TW)

(21) Appl. No.: 12/107,787

(22) Filed: Apr. 23, 2008

(30) Foreign Application Priority Data
Nov. 1, 2007 (TW) 96141209

(51) Int. Cl. H01L 29/788; H01L 21/762; H01L 21/28

(52) U.S. Cl. 257/315; 438/424; 438/593; 257/E21.546; 257/E21.19; 257/E29.3

(57) ABSTRACT

A method of manufacturing a non-volatile memory is provided. An insulating layer, a conductive material layer and a polish stop layer are sequentially on a substrate. Trenches are formed in a portion of the substrate, the polish stop layer, the conductive material layer and the insulating layer, and the conductive material layer is segmented to form conductive blocks. A dielectric material layer is formed to cover the polish stop layer and fill the trenches. A chemical mechanical polishing process is performed until exposing a surface of the polish stop layer. A portion of the dielectric layer is removed to form trench isolation structures. A portion of sidewalls of each conductive block is removed to form floating gates. A width of each floating gate is decreased gradually from bottom to top.

### CROSS-REFERENCE TO RELATED APPLICATION

This application claims the priority benefit of Taiwan application serial no. 96141209, filed on Nov. 1, 2007. The entirety the above-mentioned patent application is hereby incorporated by reference herein and made a part of specification.

### BACKGROUND OF THE INVENTION

1. Field of the Invention

The present invention relates to a memory and manufacturing method thereof, and more particularly, to a non-volatile memory and manufacturing method thereof.

2. Description of Related Art

Among various kinds of memory products, non-volatile memory is a kind of memory characterized by the advantages that it allows multiple data storing, reading, or erasing operations, and the stored data therein can be retained after the device is not powered. Hence, non-volatile memory has become a widely-adopted memory device in personal computers and electronic equipments.

Referring to FIG. 1, which is a schematic cross-sectional view of a conventional non-volatile memory. A floating gate 106a is disposed on a substrate 100 between shallow trench isolations (STI) 102. A tunneling dielectric layer 104 is disposed between the floating gate 106a and the substrate 100. An inter-gate dielectric layer 108 is compliantly disposed above the substrate 100. A control gate 110 is disposed on the inter-gate dielectric layer 108 and fills a space 112 between the neighboring floating gates 106a. A source/drain region (not shown) is disposed in the substrate 100 at two sides of a stacked gate structure, which includes the tunneling dielectric layer 104, the floating gate 106a, the inter-gate dielectric layer 108, and the control gate 110.

Referring to FIG. 2, which is a schematic cross-sectional view of another conventional non-volatile memory. The non-volatile memory shown in FIG. 2 distinguishes from other general types of non-volatile memories in the floating gate 106b. The floating gate 106b is disposed partially on the tunneling dielectric layer 104 and partially on the shallow trench isolation 102.

With scaling down integrated circuit devices, memory size is reduced with line width shrinkage. As a consequence, the space between neighboring floating gates is also narrowed as devices are miniaturized. A control gate material will not fully fill the space and easily result in the formation of holes 114 (as shown in FIG. 1 and FIG. 2), which will seriously affect the reliability and performance of memory.

To overcome the above-mentioned issue, a planarizing floating gate structure (as shown in FIG. 3) is provided by manufacturers in this field. In FIG. 3, the surface height of a floating gate 106c is approximately the same as the surface height of the shallow trench isolation 102, and a dielectric material of high dielectric constant is used as the inter-gate dielectric layer 108. These above-mentioned features distinguish the non-volatile memory shown in FIG. 3 from other non-volatile memories mentioned above. As a result, the conventional hole issues of occurring in the space between the neighboring floating gates is therefore overcome. However, the structure of this non-volatile memory (as shown in FIG. 3) will greatly reduce a coupling ratio between the control gate and the floating gate.

With the present trend of miniaturizing devices, how to maintain the level of integration and reliability of the devices within a limited space is one of the important focuses of research.

### SUMMARY OF THE INVENTION

Accordingly, the present invention provides a non-volatile memory and a manufacturing method thereof for increasing the space between the neighboring floating gates to avoid the formation of holes in subsequently filled layers without reducing the coupling ratio of the control gate and the floating gate, and furthermore, to comply with the current trend of miniaturizing devices.

The present invention is directed to a manufacturing method of non-volatile memory. First, a substrate is provided. An insulating layer, a first conductive material layer, and a polish stop layer are sequentially formed on the substrate. Then, a plurality of trenches is formed in the polish stop layer, the first conductive material layer, the insulating layer, and a portion of the substrate, and the first conductive material layer is segmented into a plurality of conductive blocks. A dielectric material layer is formed to cover the polish stop layer and fill the trenches. Then, a chemical mechanical polishing process is performed till the surface of the polish stop layer is exposed. A portion of the dielectric material layer is removed until the surface thereof is slightly higher than the surface of the insulating layer, so as to form a plurality of trench isolation structures. Thereafter, a portion of sidewalls exposed by each of the conductive blocks is removed to form a plurality of floating gates. The width of each floating gate decreases from bottom to top.

According to an embodiment of the present invention, the manufacturing method of the non-volatile memory further includes forming an inter-gate insulating layer on the floating gate and the trench isolation structure, and forming a second conductive material layer for covering the inter-gate insulating layer. A material of the inter-gate insulating layer is, for example, silicon oxide, silicon oxide/silicon nitride, or silicon oxide/silicon nitride/silicon nitride.

According to a manufacturing method of an embodiment in the present invention, a method for removing a portion of sidewalls exposed by each conductive block to form the floating gate is, for example, dry etching or wet etching.

According to a manufacturing method of an embodiment in the present invention, a material of the polish stop layer is, for example, silicon nitride or silicon oxynitride.

According to an embodiment of the present invention, the manufacturing method of the non-volatile memory further includes forming a hard mask layer on the polish stop layer before the formation of the above-mentioned trenches, and a material of the hard mask layer is, for example, amorphous carbon. In an embodiment, a forming method of the above-mentioned trenches is, for example, forming a patterned photoresist layer on the hard mask layer. Then, the patterned photoresist layer is used as a mask to etch the hard mask layer, the polish stop layer, the first conductive material layer, the insulating layer, and a portion of the substrate so as to form the trenches.

The present invention is directed to another manufacturing method of non-volatile memory. In the method, a substrate is provided first. The substrate has a memory cell region and a peripheral circuit region. An insulating layer, a first conductive material layer, and a polish stop layer are sequentially formed on the substrate. Then, a plurality of first trenches is formed in the polish stop layer, the first conductive material layer, the insulating layer, and a portion of the substrate of the memory cell region, and the first conductive material layer is segmented into a plurality of conductive blocks. Thereafter, a plurality of second trenches is formed in the polish stop layer, the first conductive material layer, the insulating layer, and a portion of the substrate of the peripheral circuit region. A dielectric material layer is formed to cover the polish stop layer, and fill the first trenches and the second trenches. A chemical mechanical polishing process is then performed till the surface of the polish stop layer is exposed. A portion of the dielectric material layer of the memory cell region is removed until the surface of the dielectric material layer is slightly higher than the surface of the insulating layer so as to form a plurality of trench isolation structures in the memory cell region. Thereafter, a portion of sidewalls exposed by each conductive block is removed to form a plurality of floating gates. The width of each floating gate decreases from bottom to top.

According to an embodiment of the present invention, the manufacturing method of the non-volatile memory further includes forming an inter-gate insulating layer on the floating gate and trench isolation structure of the memory cell region, and forming a second conductive material layer for covering an inter-gate insulating layer and a peripheral circuit region.

According to the manufacturing method of the embodiment in the present invention, a material of the inter-gate insulating layer includes, for example, silicon oxide, silicon oxide/silicon nitride, or silicon oxide/silicon nitride/silicon nitride.

According to the manufacturing method of the embodiment in the present invention, a method of removing a portion of sidewalls exposed by each conductive block to form the floating gate is, for example, dry etching or wet etching.

According to the embodiment of the present invention, the manufacturing method of the non-volatile memory further includes forming a hard mask layer on the polish stop layer before the formation of the first trenches. A material of the hard mask layer is, for example, amorphous carbon. In an embodiment, a forming method of the first trenches is, for example, forming a patterned photoresist layer on the hard mask layer of the memory cell region. Then, the patterned photoresist layer is used as a mask to etch the hard mask layer, the polish stop layer, the first conductive material layer, the insulating layer, and a portion of the substrate so as to form the trenches. In another embodiment, a forming method of the second trenches is, for example, forming an anti-reflective layer to cover the hard mask layer and fill the trenches after the formation of the first trenches. Then, a patterned photoresist layer is formed to expose a portion of the anti-reflective layer of the peripheral circuit region. The patterned photoresist layer is used as a mask to etch the anti-reflective layer, the hard mask layer, the polish stop layer, the first conductive material layer, a tunneling dielectric layer, and a portion of the substrate so as to form the second trenches.

According to an embodiment of the present invention, a material of the polish stop layer is, for example, silicon nitride or silicon oxynitride.

The present invention further provides a non-volatile memory including a substrate, a plurality of floating gates, a plurality of gate dielectric layers, and a plurality of trench isolation structures. The floating gates are disposed on the substrate, and the width of each floating gate decreases from bottom to top. The gate dielectric layers are disposed between each floating gate and the substrate respectively. The trench isolation structures are respectively disposed in the substrate between two neighboring floating gates, and the surface of each trench isolation structure is slightly higher than the surface of the gate dielectric layer.

In an embodiment, the non-volatile memory further includes an inter-gate insulating layer and a conductive material layer. The inter-gate insulating layer is disposed on the floating gates and the trench isolation structures. The conductive material layer is disposed on the inter-gate insulating layer. A material of the inter-gate insulating layer is, for example, silicon oxide, silicon oxide/silicon nitride, or silicon oxide/silicon nitride/silicon nitride.

The width of the floating gates decreases from bottom to top so that the space between the neighboring floating gates is increased to prevent the formation of holes in subsequently filled layers, and thereby affecting the performance of the device. Moreover, the present invention does not utilize a conventional fabricating process of the planarizing floating gate structure. Hence, the problem of an inferior coupling ratio between the control gate and the floating gate is prevented, so as to comply with the current trend of miniaturizing devices.

In order to make the above and other objectives, features, and advantages of the present invention more comprehensible, several embodiments accompanied with figures are described in details below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional non-volatile memory.

FIG. 2 is a schematic cross-sectional view of another conventional non-volatile memory.

FIG. 3 is a schematic cross-sectional view of yet another conventional non-volatile memory.

FIGS. 4A through 4I are schematic cross-sectional views showing a process flow of manufacturing a non-volatile memory according to an embodiment of the present invention.

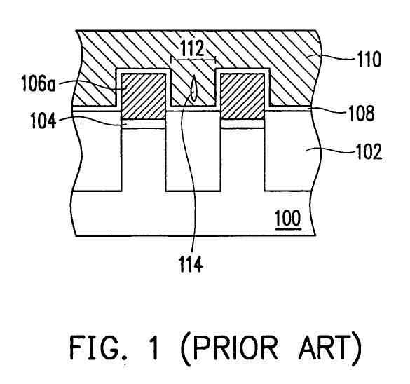

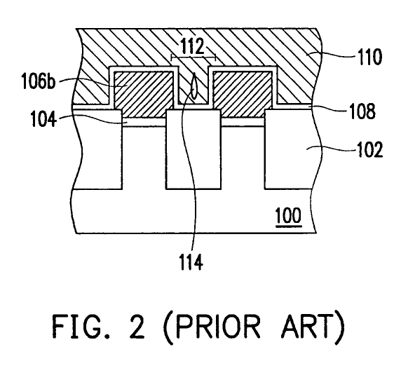

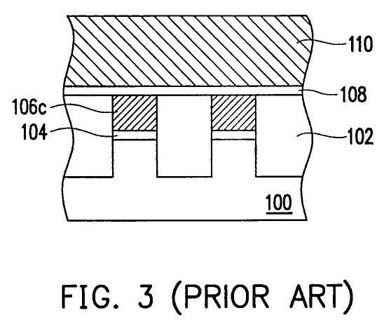

### DESCRIPTION OF EMBODIMENTS

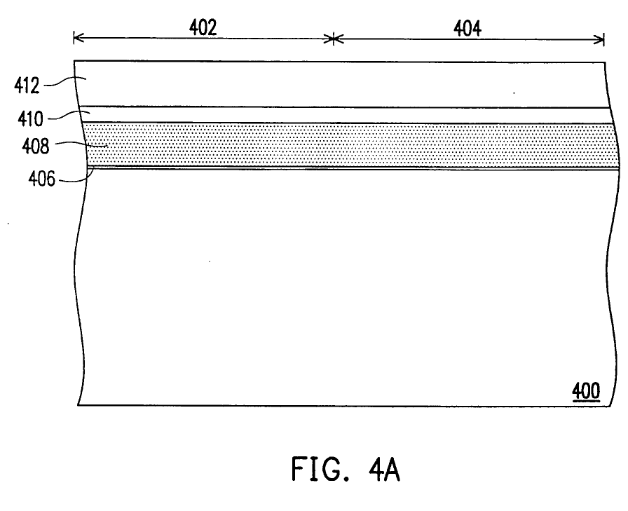

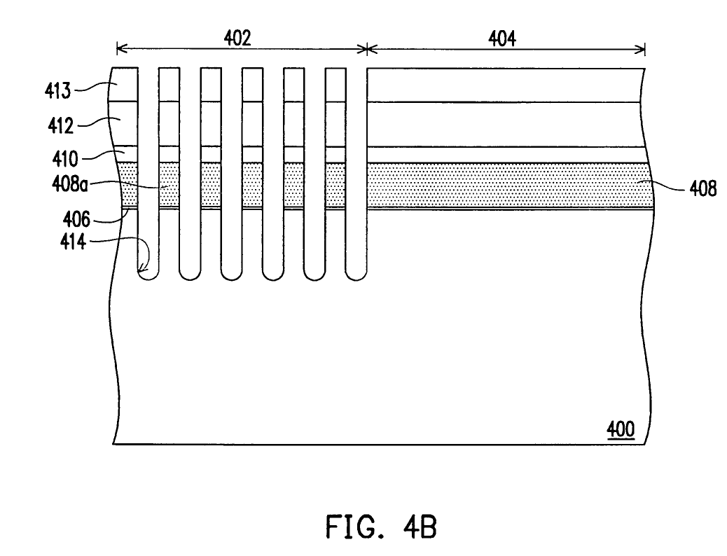

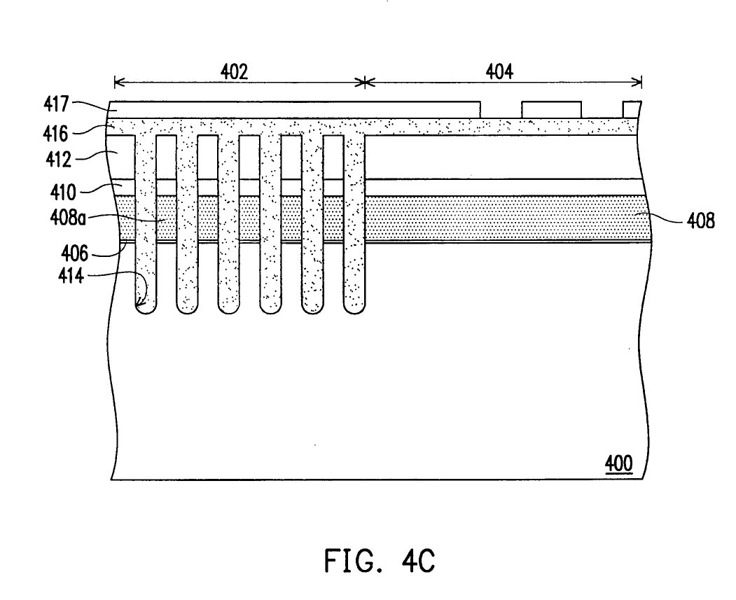

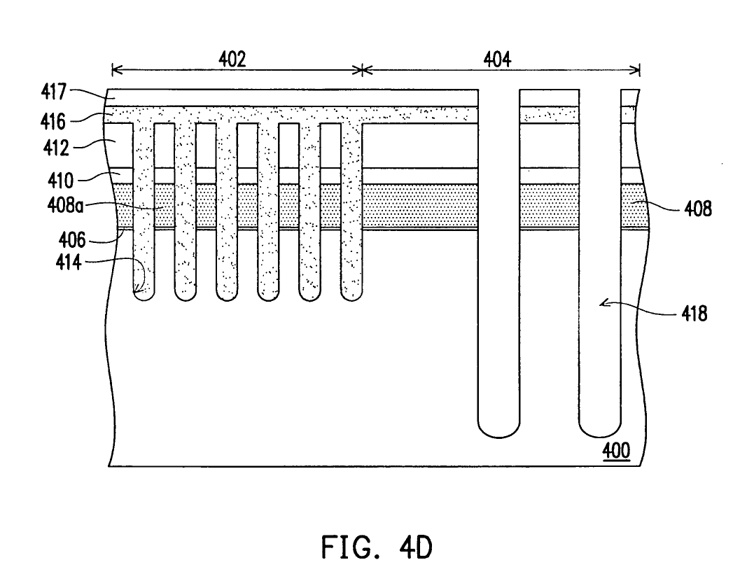

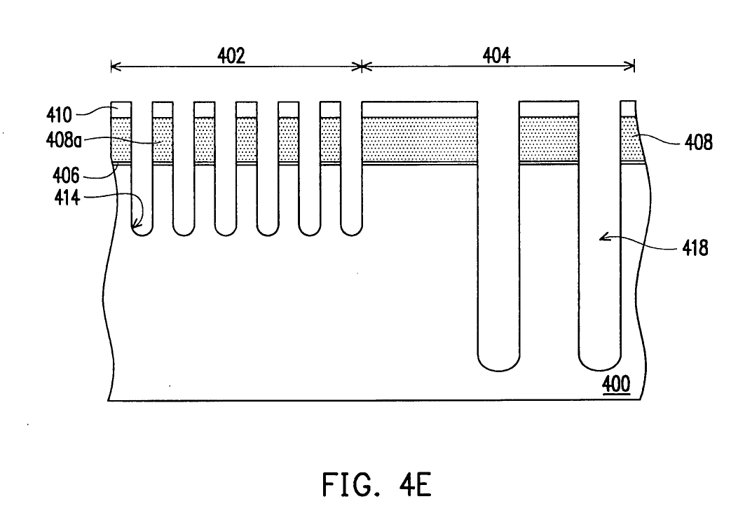

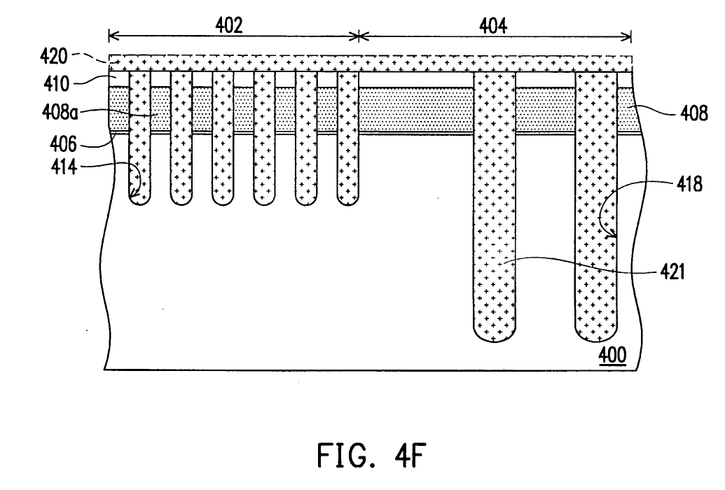

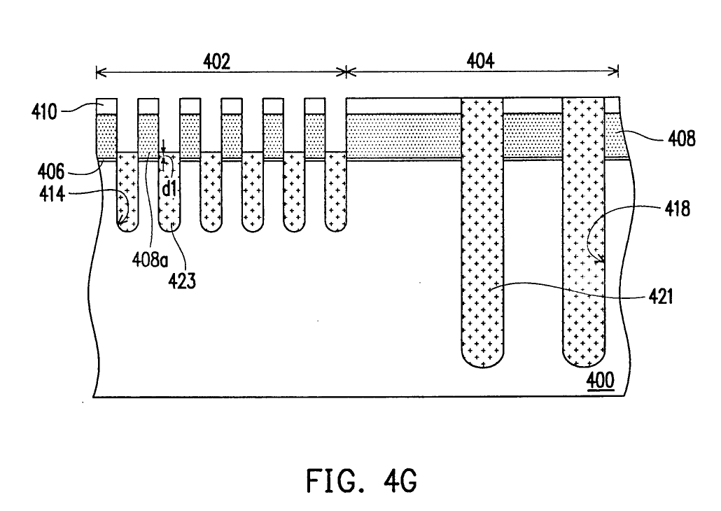

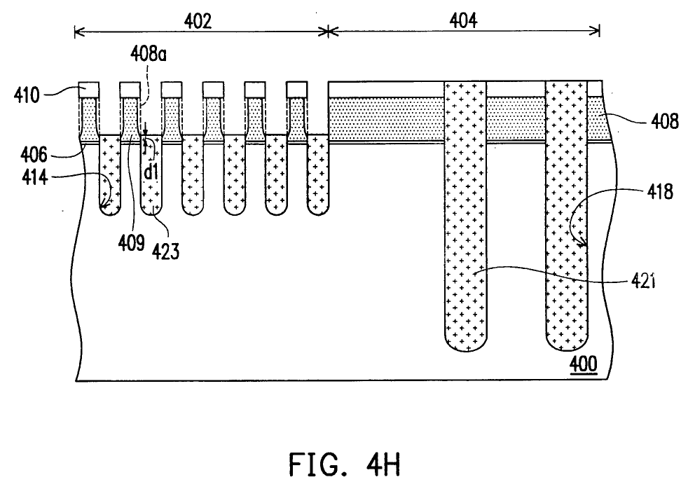

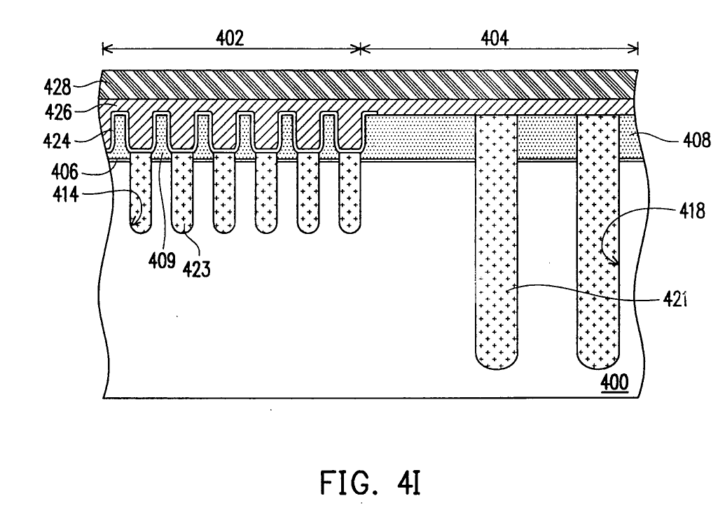

The following description further explains the process of manufacturing the non-volatile memory of the present invention. The example, however, is not intended to limit the present invention. FIGS. 4A through 4I are schematic cross-sectional views showing a process flow of manufacturing a non-volatile memory according to an embodiment of the present invention. A manufacturing method according to an embodiment of the present invention includes integrating a process of a peripheral circuit region to form a non-volatile memory simultaneously combining a memory cell region and the peripheral circuit region on a wafer. The method also includes a manufacturing method of a non-volatile memory having a memory cell region only.

First, as shown in FIG. 4A, a substrate 400 is provided. The substrate 400 is, for example, a silicon substrate or other suitable semiconductor substrates. The substrate 400 has a memory cell region 402 and a peripheral circuit region 404.

An insulating layer 406 is formed on the substrate 400 as a tunneling dielectric layer of the memory cell region 402 and a gate dielectric layer of the peripheral circuit region 404. A material of the insulating layer 406 is, for example, silicon oxide. A forming method of the insulating layer 406 is well-known to those skilled in the art, and is not further described herein.

Then, a conductive material layer 408 is formed on the substrate 400. A material of the conductive material layer 408 is, for example, doped polysilicon. A forming method of the conductive material layer 408 is, for example, performing a chemical vapor deposition (CVD) first to form an un-doped polysilicon layer and then performing an ion implanting process to form the conductive material layer 408. Alternatively, the conductive material layer 408 may also be formed by adopting an in-situ ion implanting operation and performing a chemical vapor deposition (CVD) process.

Still referring to FIG. 4A, a polish stop layer 410 is formed on the conductive material layer 408. A material of the polish stop layer 410 is, for example, silicon nitride, silicon oxynitride, or other suitable materials, and a forming method thereof is, for example, a chemical vapor deposition. Then, a hard mask layer 412 is formed on the polish stop layer 410. A material of the hard mask layer 412 is, for example, amorphous carbon or other suitable materials, and a forming method thereof is, for example, a chemical vapor deposition.

Referring to FIG. 4B, a patterned photoresist layer 413 is formed to expose a portion of the hard mask layer 412 of the memory cell region 402. Through self-alignment, the patterned photoresist layer 413 is used as a mask to etch the hard mask layer 412, the polish stop layer 410, the conductive material layer 408, the insulating layer 406, and a portion of the substrate 400 of the memory cell region 402 so as to form a plurality of trenches 414. Meanwhile, the aforementioned etching process would also segment the conductive material layer 408 so as to form a plurality of conductive blocks 408a between the neighboring trenches 414 of the memory cell region 402.

Referring to FIG. 4C, the patterned photoresist layer 413 is removed after the trenches 414 are formed. An anti-reflective layer 416 is formed to cover the hard mask layer 412 and fill the trenches 414. Thereafter, a patterned photoresist layer 417 is formed on the anti-reflective layer 416 and exposes partial anti-reflective layer 416 of the peripheral circuit region 404.

Referring to FIG. 4D, the patterned photoresist layer 417 is used as a mask to etch the anti-reflective layer 416, the hard mask layer 412, the polish stop layer 410, the conductive material layer 408, the insulating layer 406, and a portion of the substrate 400 of the peripheral circuit region 404 to form a plurality of trenches 418.

Then, referring to FIG. 4E, the patterned photoresist layer 417, the anti-reflective layer 416, and the hard mask layer 412 are removed. A method of removing the above layers is well-known to those skilled in this art, and thus no further descriptions are provided herein.

Referring to FIG. 4F, a dielectric material layer 420 (indicated by a dotted line) is formed above the substrate 400 to cover the polish stop layer 410 and to fill the trenches 414-418. Then, a chemical mechanical polishing process is performed to remove the excessive dielectric material layer 420 till the surface of the polish stop layer 410 is exposed. The trenches 418 of the peripheral circuit region 404 and the dielectric material layer 420 therein are used as a trench isolation structure 421.

Referring to FIG. 4G, for example, a photoresist layer (not shown) is formed to cover the layers of the peripheral circuit region 404. Next, the photoresist layer is used as an etching mask to remove a portion of the dielectric material layer 420 of the memory cell region 402 till the surface of the dielectric material layer 420 is slightly higher than the surface of the insulating layer 406 so as to form a plurality of trench isolation structures 423 in the memory cell region 402. The trench isolation structures 423 are, for example, 15 nm (dl) higher than the surface of the substrate 400. And, the surface height of the conductive block 408a is, for example, 80 nm higher than the surface of the substrate 400.

Referring to FIG. 4H, a portion of sidewalls on the conductive block 408a is removed to form a plurality of floating gates 409. A method of forming the floating gates 409 includes removing a portion of sidewalls of the conductive block 408a by, for example, dry etching, wet etching, or other suitable processes. Wet etching, for example, is performed by using APM solution (NH₄OH:H₂O₂:H₂O) in a high temperature environment.

Please note that the bottom width of the formed floating gates 409 is approximately equal to the width of the conductive block 408a, and the top width of the floating gates 409 is smaller than the bottom width thereof, and the width of the floating gates 409 decreases from bottom to top. Therefore, the space between the neighboring floating gates 409 can be enlarged to prevent the control gate material from causing holes in the space because of the miniaturization of the conventional manufacturing method. In another aspect, the method of the present embodiment does not require the conventional manufacturing process of a planarizing floating gate structure. Therefore, the method does not incur the problem of reduced the coupling ration between the control gate and the floating gate.

The manufacturing process of the other elements, such as an inter-gate dielectric layer and a control gate, can proceed further after the floating gates 409 are formed.

Referring to FIG. 4I, phosphoric acid (H₃PO₄), for example, is used as an etchant to remove the polish stop layer 410. Then, an inter-gate insulating layer is formed above the floating gates 409 and the trench isolation structures 423 of the memory cell region 402 to serve as an inter-gate dielectric layer 424. A material of the inter-gate dielectric layer 424 is, for example, silicon oxide/silicon nitride/silicon oxide. The inter-gate dielectric layer 424 is, for example, formed by first performing a thermal oxidation process to form a first silicon oxide layer, and a silicon nitride layer and a second silicon oxide layer are then formed on the first silicon oxide layer in sequence through performing the chemical vapor deposition process. Certainly, a material of the inter-gate dielectric layer 424 can also be silicon oxide, silicon oxide/silicon nitride, or other suitable dielectric materials.

Thereafter, a conductive material layer 426 is formed above the substrate 400 to cover the inter-gate dielectric layer 424, and the trench isolation structures 421 and the conductive material layer 408 of the peripheral circuit region 404. The conductive material layer 426 is used as the control gate of the memory cell region 402 and is combined with the conductive material layer 408 of the peripheral circuit region 404 to constitute the gate structure of the device. Similarly, a material and forming method of the conductive material layer 426 are the same as those of the conductive material layer 408.

In an embodiment, a metal silicide layer 428 is selectively formed above the conductive material layer 426 to reduce the resistance of the device. A material of the metal silicide layer 428 includes, for example, tungsten silicide, titanium silicide, cobalt silicide, tantalum silicide, nickel silicide, platinum silicide, or palladium silicide. A forming method of the metal silicide layer 428 is, for example, the chemical vapor deposition process.

Next, FIG. 4I illustrates the non-volatile memory manufactured in accordance with the above-mentioned method of the present invention. The material and manufacturing method of each of the elements in the non-volatile memory are detailed as above, so they are omitted for simplicity herein.

The present embodiment provides a non-volatile memory, including a substrate 400; a floating gate 409, disposed on the substrate 400, whose width decreases from bottom to top; a gate dielectric layer (an insulating layer 406), which is respectively disposed between the floating gate 409 and the substrate 400; a trench isolation structure 423, respectively disposed in the substrate 400 between two neighboring floating gates, whose surface is slightly higher than the surface of the insulating layer 406; an inter-gate insulating layer (an inter-gate dielectric layer 424), which is disposed on the floating gate 409 and the trench isolation structure 423; and a conductive material layer 426, which is disposed on the inter-gate dielectric layer 424. Moreover, in other embodiments, a metal silicide layer 428 can be formed on the conductive material layer 426 to reduce the resistance of the device. In summary, the present invention at least has the following advantages:

1. In the present invention, the width of the floating gates decreases from bottom to top, which increases the space between two neighboring floating gates and prevents the holes from being created when layers are filled in the space subsequently.

2. The present invention avoids reducing the coupling ratio between the control gate and the floating gate, and enhances the device performance.

3. The present invention applies self-alignment and critical simplification to form the floating gates, which simplifies the manufacturing process and complies with the current trend of device miniaturization.

Although the present invention has been disclosed above by the embodiments, they are not intended to limit the present invention. Anybody skilled in the art can make some modifications and alteration without departing from the spirit and scope of the present invention. Therefore, the protecting range of the present invention falls in

What is claimed is:

1. A manufacturing method of a non-volatile memory, comprising:
forming sequentially an insulating layer, a first conductive material layer, and a polish stop layer on a substrate;
forming a plurality of trenches in the polish stop layer, the first conductive material layer, the insulating layer, and a portion of the substrate, and segmenting the first conductive material layer into a plurality of conductive blocks;
forming a dielectric material layer to cover the polish stop layer and fill the trenches;
performing a chemical mechanical polishing process until a surface of the polish stop layer is exposed;
partially removing the dielectric material layer until a surface thereof is slightly higher than a surface of the insulating layer so as to form a plurality of trench isolation structures; and
partially removing each of the conductive blocks on the sidewalls to form a plurality of floating gates, wherein a width thereof decreases from bottom to top.

2. The method of claim 1, further comprising:
forming an inter-gate insulating layer on the floating gates and the trench isolation structures; and
forming a second conductive material layer to cover the inter-gate insulating layer.

3. The method of claim 2, wherein a material constituting the inter-gate insulating layer comprises silicon oxide, silicon oxide/silicon nitride, or silicon oxide/silicon nitride/silicon oxide.

4. The method of claim 1, wherein a method of partially removing each of the conductive blocks on the sidewalls to form the floating gates comprises dry etching or wet etching.

5. The method of claim 1, wherein a material constituting the polish stop layer comprises silicon nitride or silicon oxynitride.

6. The method of claim 1, further comprising forming a hard mask layer on the polish stop layer before the formation of the trenches.

7. The method of claim 6, wherein a material constituting the hard mask layer comprises amorphous carbon.

8. The method of claim 6, wherein a method of forming the trenches comprises:
forming a patterned photoresist layer on the hard mask layer; and
using the patterned photoresist layer as a mask to etch the hard mask layer, the polish stop layer, the first conductive material layer, the insulating layer, and a portion of the substrate so as to form the trenches.

9. A method of manufacturing the non-volatile memory, comprising:
providing a substrate, comprising a memory cell region and a peripheral circuit region;
forming sequentially an insulating layer, a first conductive material layer, and a polish stop layer on the substrate;
forming a plurality of first trenches in the polish stop layer, the first conductive material layer, the insulating layer, and a portion of the substrate in the memory cell region, and segmenting the first conductive material layer into a plurality of conductive blocks;
forming a plurality of second trenches in the polish stop layer, the first conductive material layer, the insulating layer, and a portion of the substrate in the peripheral circuit region;
forming a dielectric material layer to cover the polish stop layer, and fill the first trenches and the second trenches;
performing a chemical mechanical polishing process until the surface of the polish stop layer is exposed;
partially removing the dielectric material layer of the memory cell region until a surface thereof is slightly higher than a surface of the insulating layer so as to form a plurality of trench isolation structures in the memory cell region; and
partially removing each of the conductive blocks on the sidewalls to form a plurality of floating gates, wherein a width thereof decreases from bottom to top.

10. The method of claim 9, further comprising:
forming an inter-gate insulating layer on the floating gates and the trench isolation structures of the memory cell region;
forming a second conductive material layer to cover the inter-gate insulating layer and the peripheral circuit region.

11. The method of claim 10, wherein a material constituting the inter-gate insulating layer comprises silicon oxide, silicon oxide/silicon nitride, or silicon oxide/silicon nitride/silicon oxide.

12. The method of claim 9, wherein a method of removing a portion of sidewalls exposed by each of the conductive blocks to form the floating gates comprises dry etching or wet etching.

13. The method of claim 9, further comprising forming a hard mask layer on the polish stop layer before the first trenches are formed.

14. The method of claim 13, wherein a forming method of the first trenches comprises:
forming a patterned photoresist layer on the hard mask layer of the memory cell region; and
using the patterned photoresist layer as a mask to etch the hard mask layer, the polish stop layer, the first conductive material layer, the insulating layer, and a portion of the substrate so as to form the trenches.

15. The method of claim 13, wherein a forming method of the second trenches comprises:
forming an anti-reflective layer to cover the hard mask layer and fill the first trenches after the first trenches are formed;
forming a patterned photoresist layer to expose a portion of the anti-reflective layer of the peripheral circuit region; and
using the patterned photoresist layer as a mask to etch the anti-reflective layer, the hard mask layer, the polish stop layer, the first conductive material layer, a tunnel dielectric layer, and a portion of the substrate so as to form the second trenches.

16. The method of claim 13, wherein a material constituting the hard mask layer comprises amorphous carbon.

17. The method of claim 9, wherein a material constituting the polish stop layer comprises silicon nitride or silicon oxynitride.

18. A non-volatile memory, comprising:
a substrate;
a plurality of floating gates, disposed on the substrate, wherein a width of each of the floating gates decreases from bottom to top;
a plurality of gate dielectric layers respectively disposed between each floating gate and the substrate; and
a plurality of trench isolation structures, respectively disposed in the substrate between two neighboring floating gates, wherein a surface of each of the trench isolation structures is slightly higher than a surface of the gate dielectric layer.

19. The non-volatile memory of claim 18 further comprising:
an inter-gate insulating layer disposed on the floating gates and the trench isolation structures; and
a conductive material layer, disposed on the inter-gate insulating layer.

20. The non-volatile memory of claim 19, wherein a material constituting the inter-gate insulating layer comprises silicon oxide, silicon oxide/silicon nitride, or silicon oxide/silicon nitride/silicon oxide.
